(19) United States
(12) Patent Application Publication
(10) Pub. No.: US 2006/0281310 A1
(43) Pub. Date: Dec. 14, 2006

(54) Rotating substrate support and methods of use

(75) Inventors: Jacob Smith, Santa Clara, CA (US); Alexander Tam, Union City, CA (US); R. Suryanarayanan Iyer, Santa Clara, CA (US); Sean Seutter, San Jose, CA (US); Binh Tran, San Jose, CA (US); Nir Merry, Mountain View, CA (US); Adam Brailove, Gloucester, MA (US); Robert Shydo JR., Andover, MA (US); Robert Andrews, East Kingston, NH (US); Frank Roberts, North Reading, MA (US); Theodore Smick, Essex, MA (US); Geoffrey Ryding, Manchester, MA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/147,938

(22) Filed: Jun. 8, 2005

(51) Int. Cl. H01L 21/44; C23C 16/00

(52) U.S. Cl. 438/680; 118/719

(57) ABSTRACT

A method and apparatus for processing a substrate utilizing a rotating substrate support are disclosed herein. In one embodiment, an apparatus for processing a substrate includes a chamber having a substrate support assembly disposed within the chamber. The substrate support assembly includes a substrate support having a support surface and a heater disposed beneath the support surface. A shaft is coupled to the substrate support and a motor is coupled to the shaft through a rotor to provide rotary movement to the substrate support. A seal block is disposed around the rotor and forms a seal therewith. The seal block has at least one seal and at least one channel disposed along the interface between the seal block and the shaft. A port is coupled to each channel for connecting to a pump. A lift mechanism is coupled to the shaft for raising and lowering the substrate support.

### BACKGROUND OF THE INVENTION

1. Field of the Invention

This application generally relates to the processing of semiconductor substrates and more specifically to the deposition of materials on a semiconductor substrate. More specifically, this invention relates to a rotating substrate support for use in a single-substrate deposition chamber.

2. Description of the Related Art

Integrated circuits comprise multiple layers of materials deposited by various techniques, including chemical vapor deposition. As such, the deposition of materials on a semiconductor substrate via chemical vapor deposition, or CVD, is a critical step in the process of producing integrated circuits. Typical CVD chambers have a heated substrate support for heating a substrate during processing, a gas port for introducing process gases into the chamber, and a pumping port for maintaining the processing pressure within the chamber and to remove excess gases or processing by products. Due to the flow pattern of the gases introduced into the process chamber towards the pumping port, it is difficult to maintain a uniform deposition profile on the substrate. In addition, variance in the emissivity of the internal chamber components leads to non-uniform heat distribution profiles within the chamber and, therefore, on the substrate. Such non uniformities in the heat distribution profile across the surface of the substrate further leads to non uniformities in the deposition of materials on the substrate. This, in turn, leads to further costs incurred in planarizing or otherwise repairing the substrate prior to further processing or possible failure of the integrated circuit all together.

As such, a need exists for an improved apparatus for uniformly depositing material on a substrate in a CVD chamber.

### SUMMARY OF THE INVENTION

A method and apparatus for processing a substrate utilizing a rotating substrate support are disclosed herein. In one embodiment, an apparatus for processing a substrate includes a chamber having a substrate support assembly disposed within the chamber. The substrate support assembly includes a substrate support having a support surface and a heater disposed beneath the support surface. A shaft is coupled to the substrate support and a motor is coupled to the shaft through a rotor to provide rotary movement to the substrate support. A seal block is disposed around the rotor and forms a seal therewith. The seal block has at least one seal and at least one channel disposed along the interface between the seal block and the shaft. A port is coupled to each channel for connecting to a pump. A lift mechanism is coupled to the shaft for raising and lowering the substrate support.

In another aspect of the invention, various methods of processing a substrate utilizing a rotating substrate support are provided. In one embodiment, a method for processing a substrate in a processing chamber utilizing a rotating substrate support includes the steps of placing a substrate to be processed on the substrate support and rotating the substrate in a multiple of 360 degrees throughout a process cycle. In another embodiment, the deposition rate of a material layer to be formed on the substrate is determined and the rate of rotation of the substrate is controlled in response to the determined deposition rate in order to control a final deposition profile of the material layer. In another embodiment, the speed of rotation of the substrate is controlled in response to a specified variable or variables. The variables may be at least one of temperature, pressure, calculated rate of deposition, or measured rate of deposition. In another embodiment, the substrate may be processed for a first period of time in a first orientation and then indexed to a second orientation and processed for a second period of time.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified cross sectional view of an exemplary chemical vapor deposition chamber having a rotating substrate support of the present invention;

FIG. 2 is a schematic cross sectional view of the rotating substrate support depicted in FIG. 1;

FIG. 3 is a detailed view of one embodiment of the interface between the support shaft and the rotor of the rotating substrate support;

FIGS. 4-5 are graphs depicting film thickness non-uniformity for rotating and non-rotating substrates; and

FIGS. 6A-B are film thickness variation plots for a film formed on a non-rotating and a rotating substrate, respectively.

### DETAILED DESCRIPTION

One exemplary process chamber suitable for use with a rotating substrate support as described herein is a low pressure thermal chemical vapor deposition reactor, such as, for example, a SiNgen chamber, available from Applied Materials, Inc., of Santa Clara, Calif. It is contemplated that other process chambers may also benefit from the use of the rotating substrate support described herein.

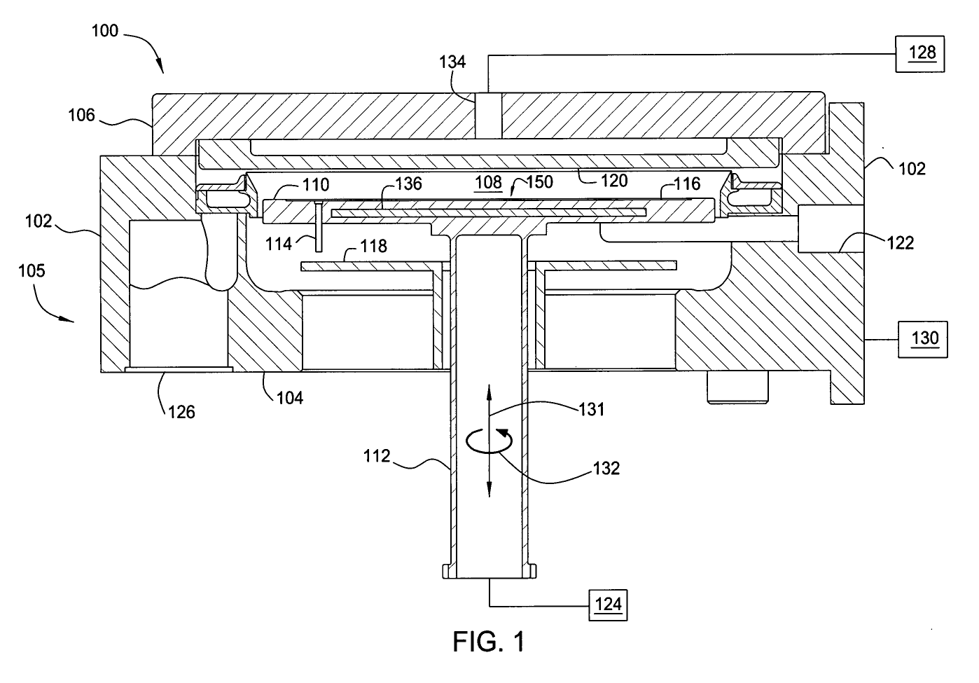

FIG. 1 illustrates one embodiment of a suitable reactor 100. The reactor 100 comprises a base 104, walls 102, and a lid 106 (collectively referred to as a chamber body 105) that define a reaction chamber, or process volume 108, in which process gases, precursor gases, or reactant gases are thermally decomposed to form a layer of material on a substrate (not shown).

At least one port 134 is formed in the lid and is coupled to a gas panel 128 that supplies one or more gases to the process volume 108. Typically, a gas distribution plate, or showerhead 120, is disposed beneath the lid 106 to more uniformly spread the process gases entering through the port 134 throughout the process volume 108. In one exemplary embodiment, when ready for deposition or processing, process gases or precursor gases provided by the gas panel 128 are introduced into the process volume 108. The process gas is distributed from the port 134 through a plurality of holes (not shown) in the showerhead 120. The showerhead 120 uniformly distributes the process gas into the process volume 108.

A pumping port 126 is formed in the chamber body 105 and is coupled to pumping equipment (not shown) such as valves, pumps, and the like, to selectively maintain the processing pressures within the chamber body 105 as needed. Other components, such as pressure regulators (not shown), sensors (not shown), and the like, may be utilized to monitor the processing pressure within the process volume 108. The chamber body 105 is constructed of materials that will enable the chamber to sustain pressures between about 10 to about 350 Torr. In one exemplary embodiment, the chamber body 105 is constructed of an aluminum alloy material.

The chamber body 105 may include passages (not shown) for a temperature controlled fluid to be pumped therethrough to cool the chamber body 105. Equipped with such temperature controlled fluid passages, the reactor 100 is referred to as a “cold-wall” or a “warm-wall” reactor. Cooling the chamber body 105 prevents corrosion to the material that is used to form the chamber body 105 due to the presence of the reactive species and the high temperature. The interior of the chamber body 105 may also be lined with a temperature-controlled liner or an insulation liner (not shown) to prevent the undesirable condensation of particles on the interior surfaces of the chamber body 105.

The reactor 100 further comprises a rotating lift assembly 150 for supporting a substrate within the process volume 108 of the reactor 100. The lift assembly 150 includes a substrate support 110, a shaft 112, and a substrate support motion assembly 124. The substrate support 110 typically houses lift pins 114 and may further include heating elements, electrodes, thermocouples, backside gas grooves, and the like (all not shown for simplicity).

In the embodiment depicted in FIG. 1, the substrate support 110 includes a heater 136 disposed beneath a substrate receiving pocket 116. The substrate receiving pocket 116 is typically approximately the thickness of a substrate. The substrate receiving pocket 116 may have a plurality of features, such as “bumps,” or stand-offs (not shown), that hold the substrate slightly above the surface of the substrate receiving pocket 116.

The heater 136 may be utilized to control the temperature of the substrate placed on the substrate support 110 during processing in order to facilitate film formation thereupon. The heater 136 generally includes one or more resistive coils (not shown) embedded in a conductive body. The resistive coils may be independently controllable to create heater zones. A temperature indicator (not shown) may be provided to monitor the processing temperature inside the chamber body 105. In one example, the temperature indicator can be a thermocouple (not shown), which is positioned such that it provides data correlating to the temperature at the surface of the substrate support 110 (or at the surface of a substrate supported by the substrate support 110).

The substrate support motion assembly 124 moves the substrate support 110 vertically up and down as well as rotationally, as depicted by arrows 131, 132. The vertical movement of the rotating lift assembly 150 facilitates transfer of the substrate into and out of the chamber body 105 and positioning the substrate within the process volume 108.

For example, a substrate is typically placed on the substrate support 110 through a port 122 formed in the walls 102 of the chamber body 105 by, for example, a robotic transfer mechanism (not shown). The substrate support motion assembly 124 lowers the substrate support 110 so that the support surface of the substrate support 110 is below the port 122. The transfer mechanism inserts the substrate through the port 122 to position the substrate above the substrate support 110. The lift pins 114 in the substrate support 110 are then raised by raising a contact lift plate 118 that is movably coupled to the base 104 of the reactor 100. The lift pins 114 lift the substrate from the transfer mechanism, which is then withdrawn. The contact lift plate 118 and lift pins 114 are then lowered to place the substrate on the substrate support 110.

Once the substrate is loaded and the transfer mechanism retracts, the port 122 is sealed, and the substrate support motion assembly 124 raises the substrate support 110 into processing position. In one exemplary embodiment, the advancement stops when the wafer substrate is a short distance (e.g., 400-900 mils) from the showerhead 120. The substrate can be removed from the chamber by essentially reversing the above steps.

The rotational movement of the rotating lift assembly 150 enables smoothing, or making more uniform, any uneven temperature distribution on the substrate during processing and provides numerous other processing advantages, as detailed below.

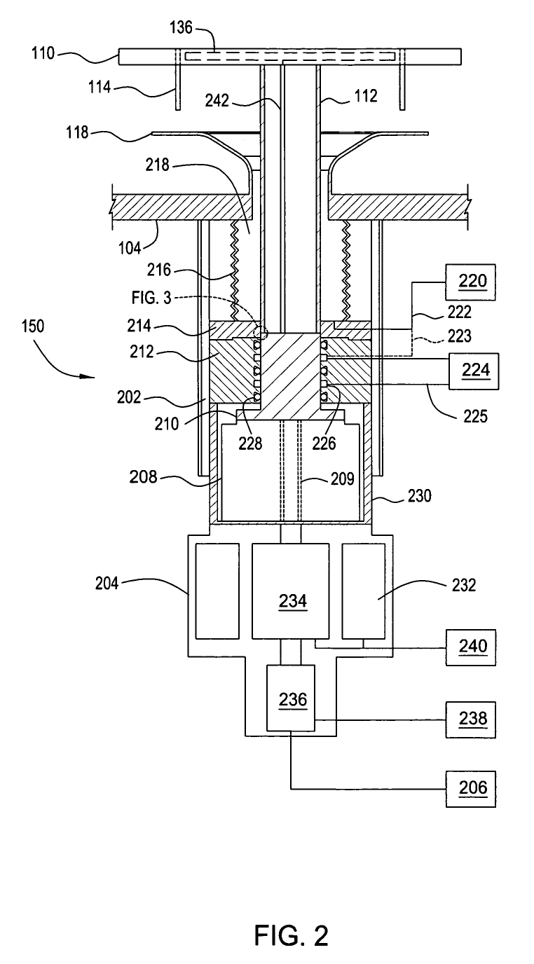

FIG. 2 depicts a cross sectional simplified view of one embodiment of the rotating lift assembly 150. In one embodiment, the rotating lift assembly 150 includes a frame 204 movably coupled to a support 202 disposed beneath the base 104 of the reactor 100. The frame 204 may be movably coupled to the support 202 by suitable means, such as linear bearings and the like. The frame supports the substrate support 110 via the shaft 112, which extends through an opening in the base 104 of the reactor 100.

A lift mechanism 206 is coupled to the frame 204 and moves the frame 204 within the support 202, thereby providing a range of motion to raise and lower the substrate support 110 within the reactor 100. The lift mechanism 206 can be a stepper motor or other suitable mechanism for providing the desired range of motion to the substrate support 110.

The frame 204 further includes a housing 230 that supports a motor 208 that is coaxially aligned with the shaft 112 and the substrate support 110. The motor 208 provides rotary motion to the substrate support 110 via a rotor 210 that is coupled to a shaft 209 of the motor 208. The shaft 209 may be hollow to allow cooling water, electrical power, thermocouple signals, and the like to be passed coaxially through the motor 208. A drive 232 may be coupled to and provide control over the motor 208.

The motor 208 typically operates in the range of between about 0 to about 60 rotations per minute (rpm) and has a steady state rotational speed variability of about 1 percent. In one embodiment, the motor 208 rotates in the range of between about 1 and about 15 rpm. The motor 208 has accurate rotational control and is index capable to within about 1 degree. Such rotational control allows for alignment of a feature, for example, a flat portion of the substrate or a notch formed on the substrate, used to orient the substrate during processing. Additionally, such rotational control allows for the knowledge of the position of any point on a substrate relative to the fixed coordinates of the interior of the reactor 100.

The substrate support 110 is supported by the motor 208 through the shaft 112 and the rotor 210, allowing the bearings of the motor 208 to support and align the substrate support 110. As the substrate support 110 is mounted to, and supported by, the motor 208, the number of components is thereby minimized and alignment and coupling problems between multiple sets of bearings may be reduced or eliminated. Alternatively, the motor 208 may be offset from the substrate support 110, using gears, belts, pulleys, and the like to rotate the substrate support 110.

Optionally, a sensor (not shown), such as an optical sensor, may be provided to prevent rotation of the substrate support 110 when the lift pins 114 are engaged with the lift plate 118 (depicted in FIG. 1). For example, the optical sensor may be disposed on the outside of the rotating lift assembly 150 and configured to detect when the assembly is at a predetermined height (e.g., a raised processing position or a lowered substrate transfer position).

The rotor 210 typically comprises a process compatible, corrosion-resistant material that reduces friction and wear to facilitate rotation, such as a hardened stainless steel, anodized aluminum, ceramic, and the like. The rotor 210 may further be polished. In one embodiment, the rotor 210 comprises 17-4PH steel that has been machined, ground, hardened, and polished. The seating surfaces at the interface between the shaft 112 and the rotor 210 are typically ground to ensure proper alignment of the substrate support 110 relative to a central axis of the motor 208 and the rotor 210.

Alignment of the substrate support 110 may be accomplished by precision machining. Alternatively or in combination, adjustment mechanisms, such as jack bolts, may also be utilized to assist in the alignment of the substrate support 110. Such alignment ensures that the central axes of the motor 208 and the substrate support 110 are parallel, thereby reducing rotational wobble of the substrate support 110. In one embodiment, the substrate support 110 has a surface run-out of between about 0.002 to about 0.003 inches. In one embodiment, the substrate support 110 has a height variation less than about 0.005 inches over a 200 mm diameter support surface. Utilization of a high quality motor 208 with good bearings further assists in reducing substrate support wobble.

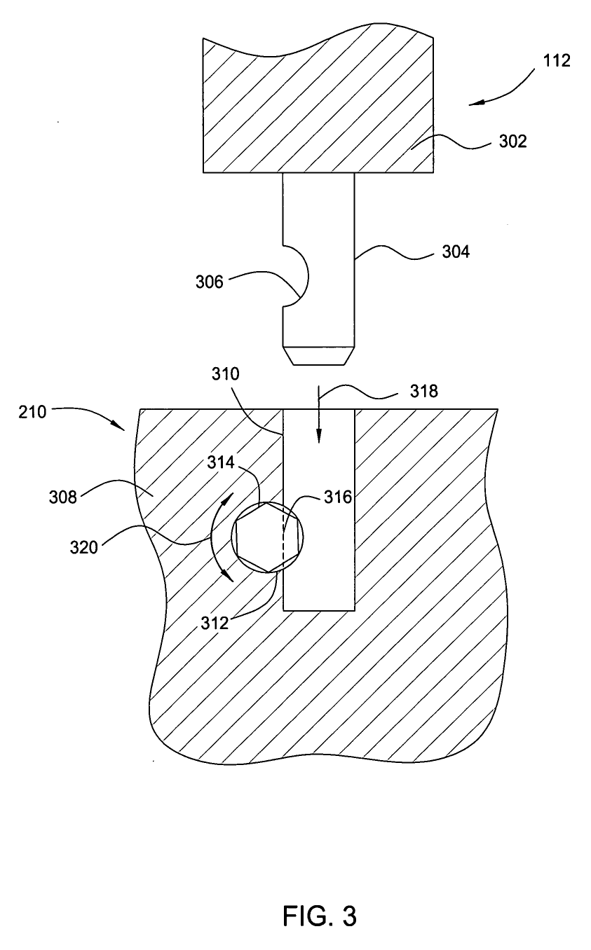

The shaft 112 of the substrate support 110 may be coupled to the rotor 210 by any suitable means such as pinning, bolting, screwing, welding, brazing, and the like. In one embodiment, the shaft 112 is removably coupled to the rotor 210 to facilitate quick and easy removal and replacement of the substrate support 110 when desired. In one embodiment, depicted in FIG. 3, a plurality of pins 304 (one shown in FIG. 3 for clarity) extend from a base 302 of the shaft 112. An aperture 310 is formed in a body 308 of the rotor 210 in a position corresponding to each of the pins 304 such that the shaft may be lowered (as indicated by arrow 318) onto the rotor 210 with the pins 304 extending into the apertures 310.

A rotatable shaft 312 extends partially into the aperture 310. A notch 316 is formed in the shaft 312 in a position that allows alignment of the notch 316 with an inner wall of the aperture 310. When so aligned, the pin 304 may extend into the aperture 310 unobstructed by the shaft 312. When fully inserted, a notch 306 formed in the pin 304 is aligned with the shaft 312. The shaft 312 may then be rotated, as indicated by arrows 320, such that the body of the shaft 312 moves into the notch 306 of the pin 304. Upon rotating the shaft 312, the body of the shaft 312 locks the shaft 112 in position. The shaft 312 may be eccentric with respect to the notch 306 of the pin 304 to facilitate engaging the pin 304 upon rotation of the shaft 312. Alternatively or in combination, the shaft 312 may have a cam (not shown) formed thereon that engages the pin 304 when the shaft 312 is rotated. To facilitate rotating the shaft 312, an outer end of the shaft 312 may have a feature, such as a hex head 314 formed thereon. The hex head 314 is positioned such that a tool may be used to more easily turn the shaft 312.

Returning to FIG. 2, in order to maintain the pressure differential between the process volume 108 inside the reactor 100 and the atmosphere outside the reactor 100, a seal block 212 surrounds the rotor 210 and forms a seal therewith. Additionally, a bellows 216 is coupled between the base 104 and the seal block 212. A mounting plate 214 may optionally be provided atop the seal block 212 to assist in the alignment of the base of the shaft 112 with the rotor 210. In the embodiment depicted in FIG. 2, the bellows 216 is coupled to the mounting plate 214 disposed on top of the seal block 212.

The seal block 212 may include at least one seal 228, for example, a lip seal, provided at the interface between the seal block 212 and the rotor 210. The seal 228 is typically abrasion resistant and may be formed from polyethylene or other process compatible material. In one embodiment, the seals are formed from polytetrafluoroethylene (PTFE). In the embodiment depicted in FIG. 2, three seals 228 are disposed between the seal block 212 and the rotor 210. To facilitate making the seal block 212 coaxial with the rotor 210, the seal block 212 may be allowed to float during installation, and thereby be centered by the pressure of the seals 228. The seal block 212 may then be bolted, clamped, or otherwise secured upon completion of the installation process.

One or more grooves, or channels 226, may further be provided along the interface between the seal block 212 and the rotor 210. The channel 226 may be formed in one or both of the seal block 212 and the rotor 210 and is connected to a pump 224 via lines 225. The pump 224 continually maintains the pressure within the channel 226 in a suitable range to maintain the seal between the interior process volume 108 of the reactor 100 and the atmosphere outside of the reactor 100. In the embodiment depicted in FIG. 2, two channels 226 are disposed in the space between the three seals 228 and are coupled to the pump 224 by two lines 225.

At least one conduit 242 is disposed within the hollow shaft 112 to couple the necessary facilities to the substrate support 110. For example, the conduit 242 may contain electrical wires to provide power for the heater 136, thermocouples and other electric connections to the substrate support. Each conduit may be formed of an insulative material, such as a ceramic, in order to shield and protect the wires. In addition, a single conduit 242 may be used for each electrical connection, thereby isolating each individual wire. Other conduits (not shown) may provide cooling gases or fluids where utilized to the substrate support 110. A slip ring 234 is provided to run electrical connections from an electrical supply 240 to the substrate support 110.

A rotary union 236 may be coupled to a coolant supply and return 238 to provide a coolant to the rotating lift assembly for use in cooling the rotor 210, the base of the shaft 112, and/or the heater 136. Alternatively or in combination, the rotor 210 may further comprise air-cooled fins (not shown) to facilitate radiant cooling of the rotor 210. In embodiments where air-cooled fins are utilized, a fan (not shown) may additionally be utilized to increase the air flow rate over the cooling fins. It is contemplated that other cooling mechanisms may be used in combination with the reactor 100 or other processing chamber having the rotating lift assembly 150. For example, a fan (not shown) may be provided outside the reactor 100 to circulate air and cool the bellows 216.

Although the slip ring 234 and the rotary union 236 or their equivalents are necessary for methods that rotate the substrate without restriction, it is contemplated that the rotary motion provided by the motor 208 could be reciprocating, rather than continuous rotation in a single direction. As such, the slip ring 234 and the rotary union 236 are considered optional if reciprocating motion is all that is required. For such an embodiment, the electrical and cooling utilities may be provided by flexible conduits (not shown) as well as through the slip ring 234 and the rotary union 236 as depicted in FIG. 2.

A purge gas supply line 225 is coupled to a purge gas supply 220 to provide a purge gas, such as nitrogen or any other process-inert gas, to an interior volume 218 of the reactor 100 disposed between the bellows 216 and the shaft 112. The purge gas in the interior volume 218 prevents the deposition of materials introduced into the reactor 100 onto the interior side of the bellows 216 and/or the shaft 112. Optionally, a purge gas may be supplied to the channels 226 from the purge gas supply 220 via a supply line 223.

Returning to FIG. 1, in one embodiment, a controller 130 is coupled to the chamber body 105 to receive signals from sensors, which indicate the chamber pressure. The controller 130 can also be coupled to the gas panel 128 to control the flow of gas or gases to the process volume 108. The controller 130 can work in conjunction with the pressure regulator or regulators to adjust or to maintain the desired pressure within the process volume 108. Additionally, the controller 130 can control the temperature of the substrate support 110, and therefore the temperature of a substrate placed thereon. The controller can further be coupled to the rotating lift assembly 150 to control the rotation thereof during processing. The controller 130 includes a memory which contains instructions in a computer readable format for controlling the gas flows as well as the pressure in the chamber and temperature of the substrate support 110 within parameters set forth above in order to form a layer of material on a substrate in accordance with the present invention.

In operation, the rotating lift assembly can be employed to minimize the impact of temperature and flow non-uniformity inherent in the processing chamber. For example, the impact from hardware manufacturing and installation tolerances, e.g., machining and materials tolerances or the installation precision of various parts, will be reduced by the smoothing effect on the flow and temperature inhomogeneities by use of the rotating lift assembly 150. The rotation creates a substrate environment that time-averages these inhomogeneities, which results in a more uniform film thickness across the substrate. The film thickness uniformity improvement applies for chambers having a gas flow inlet disposed above the wafer, as shown in FIGS. 1-2, as well as for process chambers having a gas flow inlets arranged to provide a cross-flow, or flow parallel to the substrate diameter.

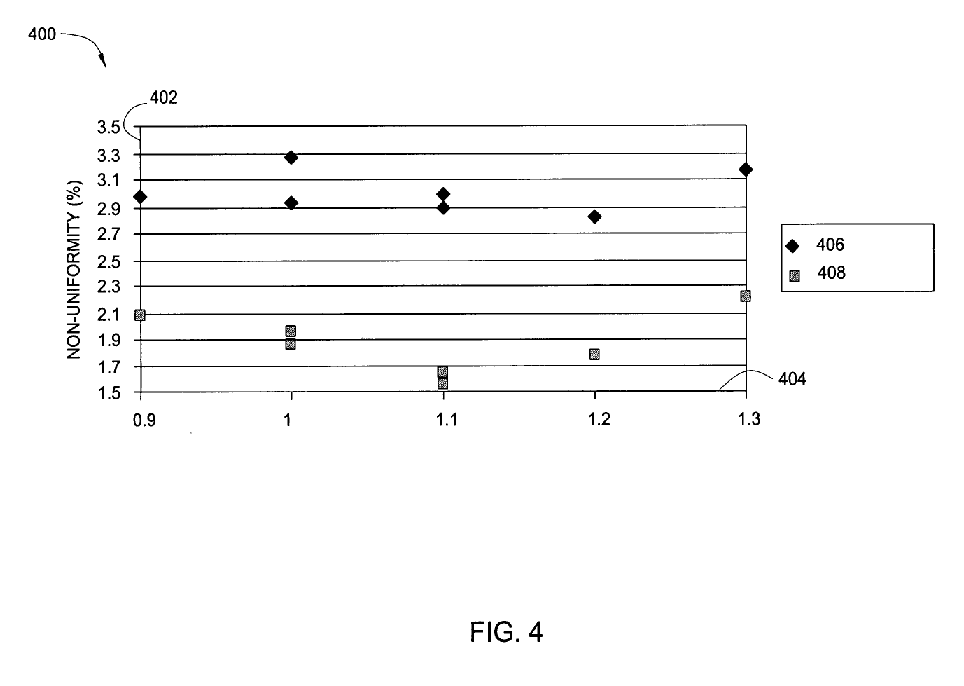

For example, FIG. 4 depicts a graph 400 of film thickness non-uniformity (axis 402), expressed as a percentage, versus a number representative of processing conditions (axis 404). The data for this chart was obtained by depositing a silicon nitride film using silane (SiH₄) and ammonia (NH₃) on a 300 mm bare silicon substrate in a CVD chamber similar to the one described above with respect to FIGS. 1-2. Data points 406 represent substrates processed without rotation. Data points 408 represent substrates processed while rotating the substrate. The data points 408 reveal lower non-uniformity percentage for substrates processed with substrate rotation, as compared to the data points 406, for all processing conditions measured (e.g., along axis 404).

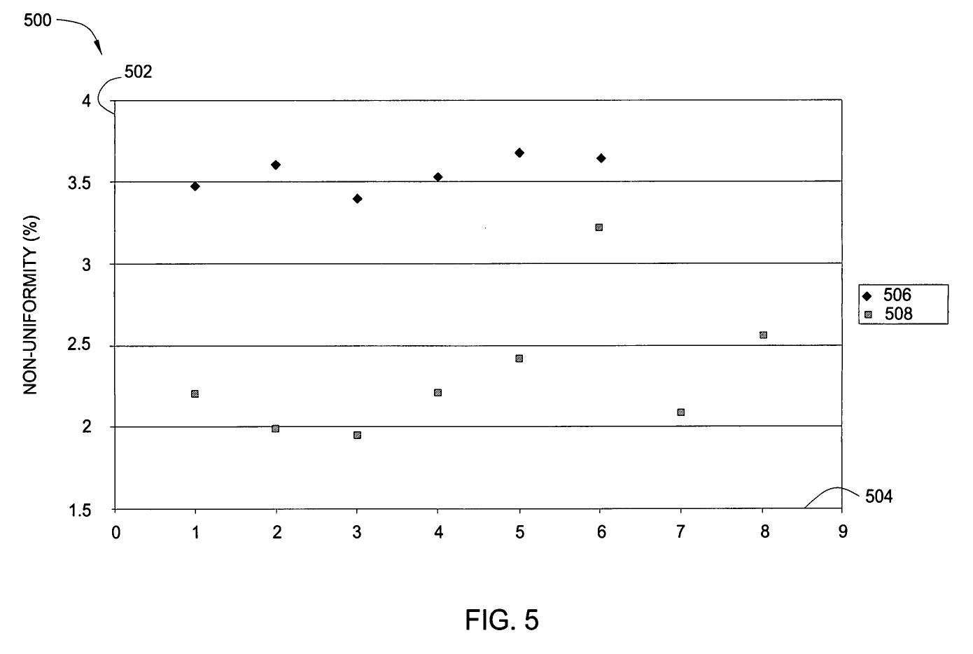

As another example, FIG. 5 depicts a graph 500 of film thickness non-uniformity, expressed as a percentage on axis 502, for several substrates processed with and without substrate rotation, numbered sequentially on axis 504. The data for this chart was obtained by depositing a silicon nitride film using bis(tert-butylamino)silane (BTBAS) and ammonia (NH₃) on a 300 mm bare silicon substrate in a CVD chamber similar to the one described above with respect to FIGS. 1-2. Data points 506 represent substrates processed without rotation. Data points 508 represent substrates processed while rotating the substrate. The data points 508 show that rotating the substrate improves, i.e., lowers, the film thickness non-uniformity percentage as compared to substrates processed without rotation (e.g., data points 506).

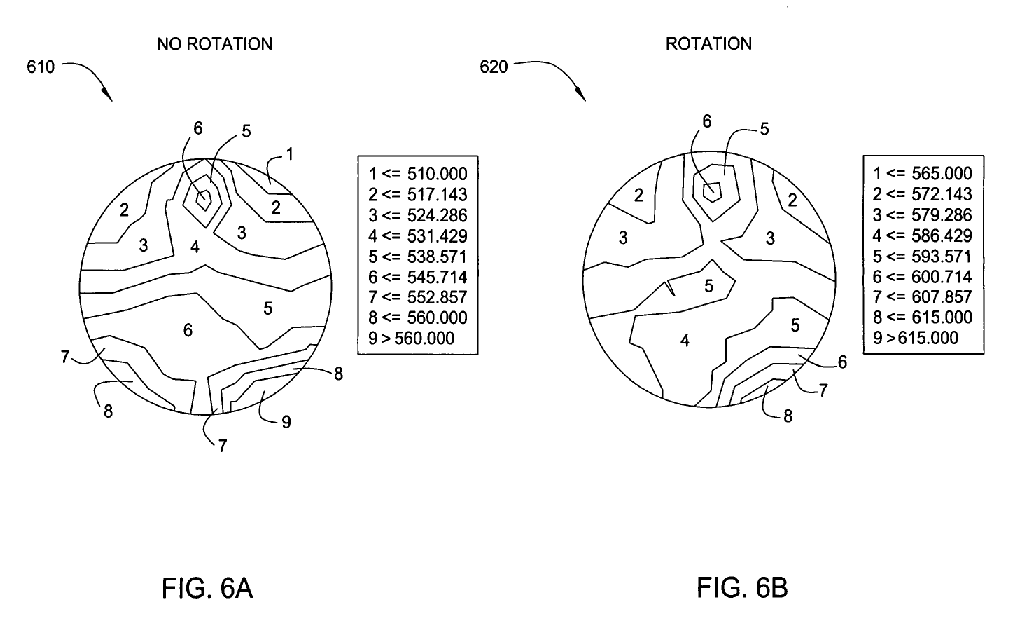

As another example, FIGS. 6A-B depict film thickness variation plots across the surface of a substrate for a film deposited on a stationary and a rotating substrate, respectively. Plot 610, depicted in FIG. 6A, shows a greater variation in film thickness across the surface of the substrate for a substrate processed without rotation as compared to plot 620, depicted in FIG. 6B, which corresponds to a substrate processed while rotating the substrate.

Another advantage of the rotating lift assembly 150 is the increased flow created by the rotation of the substrate, which may further reduce particulate contamination on a substrate. Furthermore, because of the added flow component created by the rotation of the substrate by the rotating lift assembly 150, lower total flow rates may be used thereby allowing reduction in the inert gases and other dilutants added to the reactant gases to maintain uniform flow or relatively uniform flow within the process chamber. The reduction in the dilutant gases advantageously increases the deposition rate due to the greater concentration of reactant species in the process volume 108 of the reactor 100.

Examples of methods of use of the rotating lift assembly 150 described above are provided below. In one embodiment, the substrate may be in multiples of 360 degrees (including 360 degrees) throughout a particular process cycle. Alternatively, the substrate may be rotated multiples of 360 degrees through at least one of a process ramp-up portion, a steady-state portion, and/or a ramp-down portion of a particular process cycle.

In another embodiment, a substrate supported on a substrate support 110 may be rotated during a particular process to deposit a uniform seed layer of material. Subsequent to the deposition of the seed layer, bulk deposition over the seed layer may then proceed with or without rotation of the substrate support 110.

A substrate may be monitored by appropriate profiling equipment such that the rotation of a substrate supported on the rotating lift assembly 150 may be controlled over the course of multiple process cycles in order to get a desired deposition profile within each process cycle. The deposition profiles may be monitored and adjusted appropriately for each subsequent deposition cycle such that the total deposition thickness profile equals a desired profile (e.g., flat).

Furthermore, the speed of the rotation of the rotating lift assembly 150 may be varied depending upon particular variables that are measured or monitored during the processing of the substrate. For example, process variables known to affect deposition rates, such as temperature or pressure, or a measured or calculated rate of deposition may be utilized to control the speed of rotation of the substrate supported by the substrate support 110 during processing. For example, the substrate may be rotated at slower speeds during slow deposition rate periods and at faster speeds during faster deposition rate periods.

In addition, the substrate supported by the rotating lift assembly 150 may be incrementally indexed during processing, rather then uniformly rotated. For example, you can process a substrate in one position for a certain period of time then index the substrate to a new position for a subsequent period of time. For example, the substrate may be held in a first orientation for a first period of time, the rotated 180 degrees into a second orientation and processed for a second period of time.

The substrate may also be indexed in order to align a substrate for removal from the chamber. The indexing capability may also be used to retain knowledge of the substrate orientation within the chamber so that process non-uniformities or defects detected on the substrate can be correlated to a specific region of the reactor 100.

While the above methods and apparatus relate to a low temperature chemical vapor deposition chamber, it is contemplated that other chambers and other thin-film deposition processes may be adapted to benefit from the rotating substrate support 150 described herein. For example, the rotating lift assembly may be utilized to provide improved film thickness uniformity in atomic layer deposition (ALD) processes, which pulse gas precursors separately to deposit a film in one atomic layer per cycle. Alternatively, the rotating lift assembly may be utilized to provide improved film thickness uniformity in ultraviolet (UV) light- or plasma-enhanced thermal deposition processes, which respectively utilize UV light or a plasma to increase chemical reactivity.

While the foregoing is directed to embodiments of the present invention, other and further embodiments of the invention may be devised without departing from the basic scope thereof, and the scope thereof is determined by the claims that follow.

1. An apparatus for processing a substrate, comprising:
a chamber; and
a substrate support assembly disposed within the chamber, the substrate support assembly comprising:
a substrate support having a support surface;
a heater disposed beneath the support surface;
a shaft coupled to the substrate support;
a motor coupled to the shaft through a rotor to provide rotary movement to the substrate support;
a seal block disposed around the rotor and forming a seal therewith, the seal block having at least one seal and at least one channel disposed along the interface between the seal block and the shaft and a port coupled to each channel for connecting to a pump; and
a lift mechanism coupled to the shaft for raising and lowering the substrate support.

2. The apparatus of claim 1, wherein the motor rotates at a speed of up to about 60 rotations per minute.

3. The apparatus of claim 1, wherein the motor has a steady state rotational variation of within about 1 percent.

4. The apparatus of claim 1, wherein the motor is index capable to less than about 1 degree.

5. The apparatus of claim 1, wherein the seal block further comprises:
a plurality of seals disposed at the interface between the seal block and the shaft, wherein at least one channel is disposed between two of the plurality of seals.

6. The apparatus of claim 1, wherein the seal block further comprises:
three seals and two channels disposed at the interface between the seal block and the shaft, wherein each of the two channels is disposed between two of the three seals.

7. The apparatus of claim 1, further comprising:
a plurality of apertures formed in an upper surface of the rotor; and
a plurality of pins disposed on a bottom of the shaft and extending into the plurality of apertures.

8. The apparatus of claim 7, further comprising:
a notch formed in each pin; and
a rotatable shaft partially protruding into the aperture and having a notch formed therein that, when aligned, allows free movement of the pin into and out of the aperture and, when not aligned prevents the movement of the pin out of the aperture by extending into the notch of the pin.

9. The apparatus of claim 1, further comprising:
three apertures formed in an upper surface of the rotor; and
three pins disposed on a bottom of the shaft, each pin extending into a corresponding one of the three apertures.

10. The apparatus of claim 1, further comprising:
at least one insulative conduit disposed within the shaft and extending from a bottom surface of the substrate support to a bottom portion of the shaft.

11. The apparatus of claim 1, further comprising:
a controller coupled to the substrate support assembly and containing instructions to rotate the substrate support assembly during processing.

12. The apparatus of claim 1, wherein the substrate support is coupled coaxially with the motor, and wherein bearings of the motor support and position the heater.

13. The apparatus of claim 1, wherein the substrate support is driven directly by the motor.

14. A method of processing a substrate in a processing chamber utilizing a rotating substrate support, comprising:
placing a substrate to be processed on the substrate support; and
rotating the substrate in an integral multiple of 360 degrees over the course of a process cycle including delivering gas into the chamber.

15. The method of claim 14, wherein the step of rotating further comprises:
rotating the substrate in an integral multiple of 360 degrees through at least one of a process ramp-up portion, a steady-state portion, and/or a ramp-down portion of the process cycle.

16. The method of claim 14, wherein the process cycle is part of a chemical vapor deposition process.

17. The method of claim 14, wherein the process cycle is part of a atomic layer deposition process.

18. A method of processing a substrate in a processing chamber utilizing a rotating substrate support, comprising:
placing a substrate to be processed on the substrate support;
determining the deposition rate of a material layer to be formed on the substrate; and
controlling the rate of rotation of the substrate in response to the determined deposition rate in order to control a final deposition profile of the material layer.

19. The method of claim 18, further comprising:
repeating the determining and controlling steps over the course of multiple process cycles in order to get a desired final deposition profile at the conclusion of a final process cycle.

20. The method of claim 19, wherein the multiple process cycles are part of an atomic layer deposition process.

21. A method of processing a substrate in a processing chamber utilizing a rotating substrate support, comprising:
placing a substrate to be processed on the substrate support; and
controlling the speed of rotation of the substrate in response to a specified variable or variables.

22. The method of claim 21, wherein the specified variable is at least one of temperature, pressure, calculated rate of deposition, or measured rate of deposition.

23. The method of claim 21, wherein the step of controlling the speed of rotation further comprises:
slowing the rate of rotation during slower deposition rate periods; and
increasing the rate of rotation during faster deposition rate periods.

24. A method of processing a substrate in a processing chamber utilizing a substrate support, comprising:
placing a substrate to be processed on the substrate support;
processing the substrate for a first period of time in a first orientation; and
indexing the substrate to a second orientation and processing the substrate for a second period of time.
